(19) United States
(12) Patent Application Publication
(10) Pub. No.: US 2007/0275565 A1
(43) Pub. Date: Nov. 29, 2007

(54) FULL REMOVAL OF DUAL DAMASCENE METAL LEVEL

(76) Inventors: Edward C. Cooney III, Jericho, VT (US); Robert M. Geffken, Burlington, VT (US); Vincent J. McGahay, Poughkeepsie, NY (US); William T. Motsiff, Essex Junction, VT (US); Mark P. Murray, Stowe, VT (US); Amanda L. Piper, Poughkeepsie, VT (US); Anthony K. Stamper, Williston, VT (US); David C. Thomas, Richmond, VT (US); Elizabeth T. Webster, Burlington, VT (US)

Correspondence Address: FREDERICK W. GIBB, III;Gibb & Rahman, LLC, 2568-A RIVA ROAD, SUITE 304, ANNAPOLIS, MD, 21401, US

(21) Appl. No.: 11/838,942

(22) Filed: Aug. 15, 2007

Related U.S. Application Data
(62) Division of application No. 10/250,147, filed on Jun. 6, 2003.

(51) Int. Cl. H01L 21/311

(52) U.S. Cl. 438/736; 438/740; 257/E21.252

(57) ABSTRACT

A method and structure for semiconductor structure includes a plurality of adjacent wiring levels, conductors within each of the wiring levels, and liners at least partially surrounding each of the conductors. The liners of adjacent wiring levels are made of different materials which have different etching characteristics and are selectively etchable with respect to one another. The liners can be tantalum, tungsten, etc. The liners surround at least three sides of the conductors. Each of the wiring levels has a first insulator layer which has a first dielectric material. The liners and the conductors are positioned within the first dielectric material. A second insulator layer has a second dielectric material over the first insulator layer. The first dielectric material has a lower dielectric constant than the second dielectric material. The first dielectric material can be silicon dioxide, fluorinated silicon dioxide (FSD), microporous glasses, etc. The second dielectric material can be one of nitrides, oxides, tantalum, tungsten, etc.

### CROSS-REFERENCE TO RELATED APPLICATIONS

This application is a divisional of U.S. application Ser. No. 10/250,147 filed Jun. 6, 2003, the complete disclosure of which, in its entirety, is herein incorporated by reference.

### BACKGROUND OF THE INVENTION

1. Field of the Invention

The present invention generally relates to integrated circuit processing, and more particularly to methods relating to integrated circuit rework processes on semiconductor wafers.

2. Description of the Related Art

Currently, integrated circuit BEOL (back end of the semiconductor processing line) rework processes are used for both ASIC (Application Specific Integrated Circuit) design qualifications and normal production. These rework processes have been developed for both aluminum oxide and copper oxide multi-level-metal wiring and are generally employed to correct yield or reliability problems or a photomask error. Such rework processes enable QTAT (quicker turn around time) design verification and save integrated circuit fabrication costs. An example of a rework process is given in U.S. Pat. No. 6,332,988, the complete disclosure of which is herein incorporated by reference, wherein a process for reworking electroplated solder bump wafers is disclosed.

The introduction of copper and low dielectric (k) technologies presents the opportunity for additional rework process definition because the physical and chemical properties of low k dielectric materials differ significantly from silicon dioxide, and therefore are not amenable to the same rework procedures. Such rework processes must integrate with POR BEOL (process of record back-end-of-line) processing sequences, maintain planarity throughout the rework process, remove multiple thin films including Si₃N₄, low k organic dielectrics, copper, and liner materials, and stop on BPSG/W (Boron Phosphorous Silicate Glass/Tungsten). Some conventional processes teach methods for reworking a defective SiLK® layer caused by improper patterning and etching such as for a photoresist lithography process. However, these conventional processes do not address rework of the final integrated metal in addition to the dielectric BEOL.

Additionally, as integrated circuit device dimensions shrink with each successive technology, the pitch at the lower wiring levels becomes challenging with respect to photolithographic overlay shorting, via resistance of copper to copper vias in low k materials, metal line to metal line capacitance, and metal level to metal level cooling issues.

Therefore, there is a need for an integrated circuit rework process which results in additional vertical space between any or all BEOL levels, and which would be instrumental in facilitating removal and reconstruction of defective BEOL levels and in securing desired process window latitude with respect to overlay, via resistance, line capacitance, and cooling.

### SUMMARY OF THE INVENTION

In view of the foregoing and other problems, disadvantages, and drawbacks of the conventional rework processes, the present invention has been devised, and it is an object of the present invention to provide a method for a single and multilevel rework processing.

In order to attain the object above, there is provided, according to one aspect of the invention, a semiconductor structure that includes a plurality of adjacent wiring levels, conductors within each of the wiring levels, and liners at least partially surrounding each of the conductors. The liners of adjacent wiring levels are made of different materials which have different etching characteristics and are selectively etchable with respect to one another. The liners can be tantalum, tungsten, etc. The liners surround at least three sides of the conductors. Each of the wiring levels has a first insulator layer which has a first dielectric material. The liners and the conductors are positioned within the first dielectric material. A second insulator layer has a second dielectric material over the first insulator layer. The first dielectric material has a lower dielectric constant than the second dielectric material. The first dielectric material can be silicon dioxide, fluorinated silicon dioxide (FSD), microporous glasses, etc. The second dielectric material can be one of nitrides, oxides, tantalum, tungsten, etc.

The invention also includes the method of reworking wiring levels in a semiconductor structure. The wiring levels have liners at least partially surrounding conductors. The invention removes the first conductors from a first wiring level. The first liners at least partially surround the first conductors within the first wiring level. The invention also protects second conductors of a second wiring level, adjacent the first wiring level, during the process of removing the first conductors. The invention then removes the first liners from the first wiring level. The first liners are a different material than second liners in the second wiring level. The first liners include a material having different etching characteristics than the second liners. The first liners and the second liners are selectively etchable with respect to one another such that the process of removing the first liners does not affect the second liners. The invention also removes an insulator surrounding the first liners in the first wiring level. After the removing of the first liners, the invention planarizes the semiconductor structure to completely remove the first wiring level. The invention removes the first conductors in an etching process that attacks the conductors and does not attack the first liners or the second liners. The invention also removes the first liners in a selective etching process that removes the first liners does not affect the second liners.

With the invention, the liners of adjacent wiring levels comprise different materials that have different etching characteristics and that are selectively etchable with respect to one another. The invention provides an etchant that will attack only one of the liners and that will not affect the other liner. The underlying metal layer is protected its corresponding liner when the overlying metal liner is removed. This allows the invention to easily and completely remove one metal layer without affecting the adjacent metal layer.

### BRIEF DESCRIPTION OF THE DRAWINGS

The foregoing and other objects, aspects and advantages will be better understood from the following detailed description of a preferred embodiment(s) of the invention with reference to the drawings, in which:

FIG. 1 is a cross-sectional schematic diagram of an integrated circuit structure undergoing rework processing according to the present invention;

FIG. 2 is a cross-sectional schematic diagram of an integrated circuit structure undergoing rework processing according to the present invention;

FIG. 3 is a cross-sectional schematic diagram of an integrated circuit structure undergoing rework processing according to the present invention;

FIG. 4 is a cross-sectional schematic diagram of an integrated circuit structure undergoing rework processing according to the present invention;

FIG. 5 is a cross-sectional schematic diagram of an integrated circuit structure undergoing rework processing according to the present invention;

FIG. 6 is a cross-sectional schematic diagram of an integrated circuit structure undergoing rework processing according to the present invention; and

FIG. 7 is a flow diagram illustrating a preferred method of the invention.

### DETAILED DESCRIPTION OF PREFERRED EMBODIMENTS OF THE INVENTION

With the invention, the liners of adjacent wiring levels comprise different materials that have different etching characteristics and that are selectively etchable with respect to one another. The invention provides an etchant that will attack only one of the liners and that will not affect the other liner. The underlying metal layer is protected its corresponding liner when the overlying metal liner is removed. This allows the invention to easily and completely remove one metal layer without affecting the adjacent metal layer.

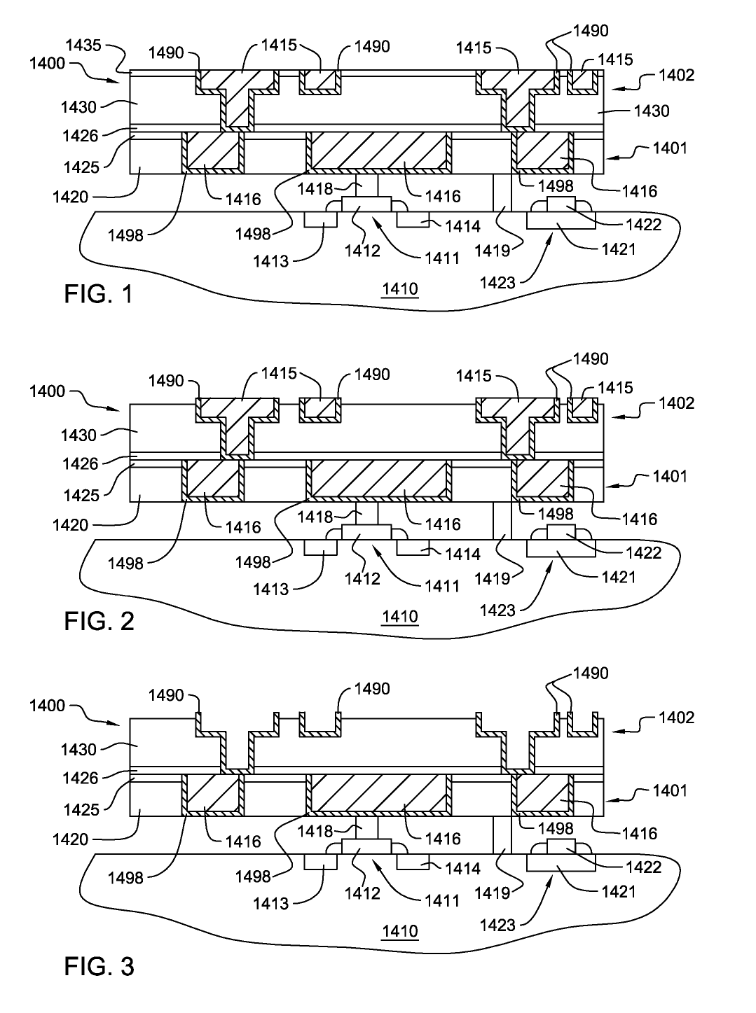

Referring now to the drawings, and more particularly to FIGS. 1 through 6, there are shown preferred embodiments of the method and structures according to the present invention. In FIG. 1, a multilevel integrated circuit structure 1400 is shown formed on top of a BPSG/W substrate 1410, which may contain integrated devices, such as MOS (metal oxide semiconductors), transistors, capacitors, etc., that has been passivated with a dielectric, such as BPSG, PSG, etc. For example, FIG. 1 illustrates two such devices, a transistor 1411 and a capacitor 1423. The transistor 1411 includes a gate 1412, and source and drain regions 1413, 1414. The gate 1412 is electrically connected to the conductor 1416 by a contact 1418. The capacitor 1423 includes a conductor 1422, an oxide 1421, and another conductor 1419.

A first insulator layer 1420 is above the substrate 1410 and preferably is a low dielectric constant material (low k dielectric), such as SiLK®, available from Dow Chemical Company, N.Y., USA, FLARE®, available from Honeywell, N.J., USA, and traditional materials such as silicon dioxide, fluorinated silicon dioxide (FSG), and microporous glasses such as Nanoglass®, available from Honeywell, Inc., N.J., USA, as well as organo-silicate glass (OSG) (SiCₓO_{y}H_{z}) Black Diamond, available from Applied Material, Calif., USA; Coral, available from Novellus Systems, Inc., Calif., USA; Auroa, available from ASM, Holland, Amsterdam. Xerogel, available from Allied Signal, N.J., USA; and carbides (SiCₓN_{y}H_{z}). In FIG. 1, the metal contacts and wires 1415 are defective (under-etched, misaligned with an underlying layer, scratched, designed incorrectly, etc.) and, therefore, the metal layer 1402 needs to be reworked (removed and reformed).

A first hardmask layer 1425 comprising one of nitrides, oxides, such as FSG, SiO₂, OSG, is above the first insulator layer 1420. The hardmask layer 1425 could also comprise multiple capping layers such as SiO₂, SiN, SiC, OSG, etc. A second insulator layer 1430 comprising a low dielectric constant material, such as SiLK®, FLARE®, and traditional materials such as silicon dioxide and fluorinated silicon dioxide (FSG), and microporous glasses, such as those discussed above, is above the first hardmask layer 1425. Then, a second hardmask layer 1435, similar to the first hardmask layer 1425, is above the second insulator layer 1430. The second or subsequent hard masks could comprise metals or insulators.

The first insulator layer 1420 and first hardmask layer 1425 surround (or at least partially surround on three sides) a first single damascene metallization layer 1401, while the second insulator layers 1426, 1430 and the second hardmask layer 1435 surround a second dual damascene metallization layer 1402. Interspersed within the first and second metallization layers 1401, 1402 of the integrated circuit structure 1400 are a plurality of wiring conductors 1415, 1416, preferably comprising copper, polysilicon, metal alloys, refractory metals, etc.

The terms “single damascene” and “dual damascene” are used herein to reference the well-known processes of forming different types and shapes of metallization layers. For example, wiring layer 1401 is formed by patterning openings in the insulators 1420, 1425, depositing a conformal layer of the liner 1498, and planarizing the structure such that the liner 1498 only remains within the pattern openings. Then, the lined openings are filled (in a damascene process) with the conductor 1416 and the structure is planarized so that the next insulator 1426 can be applied to a planar surface. To form the upper wiring layer 1402, a well-known dual damascene process is used. Such a process first forms narrow deep openings in the insulator layers 1435, 1430, and 1426. These openings are lined with the liner 1490 and filled with the conductor 1415 in a first damascene process. Next, in a second the damascene process, wider, less deep openings are formed in the insulators 1435, 1430. These openings are also lined and filled with the liner 1490 and conductor 1415. This dual damascene approach provides the unique contact shapes and the additional shallow wiring layers shown in FIG. 1.

Thus, as shown, a preferred structure for the present invention is one in which successive BEOL levels are formed using different conductor liner materials 1498, 1490, which can be removed using different materials, such as etchants, etc. For example, the first BEOL level 1401 can comprise a W, TiN, Ta, TaN, TaSiN, WN, WSiN, etc., liner 1498, while the second BEOL level 1402 can comprise a similar liner 1490 that is selectively etchable with respect to the first liner 1498. Alternatively, non-refractory metals can be used for the liners. As shown in the drawings, the liners 1490, 1498 at least partially surround the conductors 1415, 1416. In this example, the liners 1490, 1498 surround the conductors 1415, 1416 on three sides.

Thus, stated more generally level M. is formed with one type of liner, and levels Mₓ₊₁ and Mₓ₋₁ are formed of a different type of liner. In other words, the tungsten and tantalum liners alternate at each successive metal level. With the invention, the liners of adjacent wiring levels comprise different materials that have different etching characteristics and that are selectively etchable with respect to one another.

As shown in FIG. 2, the integrated circuit structure 1400 can undergo a RIE (reactive ion etching) process wherein the second hardmask layer 1435 is removed from the top of the second metallization layer 1402, thereby exposing the upper surfaces of some of the wiring conductors 1415, 1416. The RIE process preferably comprises perfluorocarbon (PFC) (CFₓ,CHₓF_{y}), hydrofluorocarbon (HFC), PFC-HFC-Argon passivation using a parallel plate plasma, downstream plasma, HDP or other plasma processing as known in the art with or without an oxidizer such as O₂, CO₂, NO, NO₂, CO, etc.

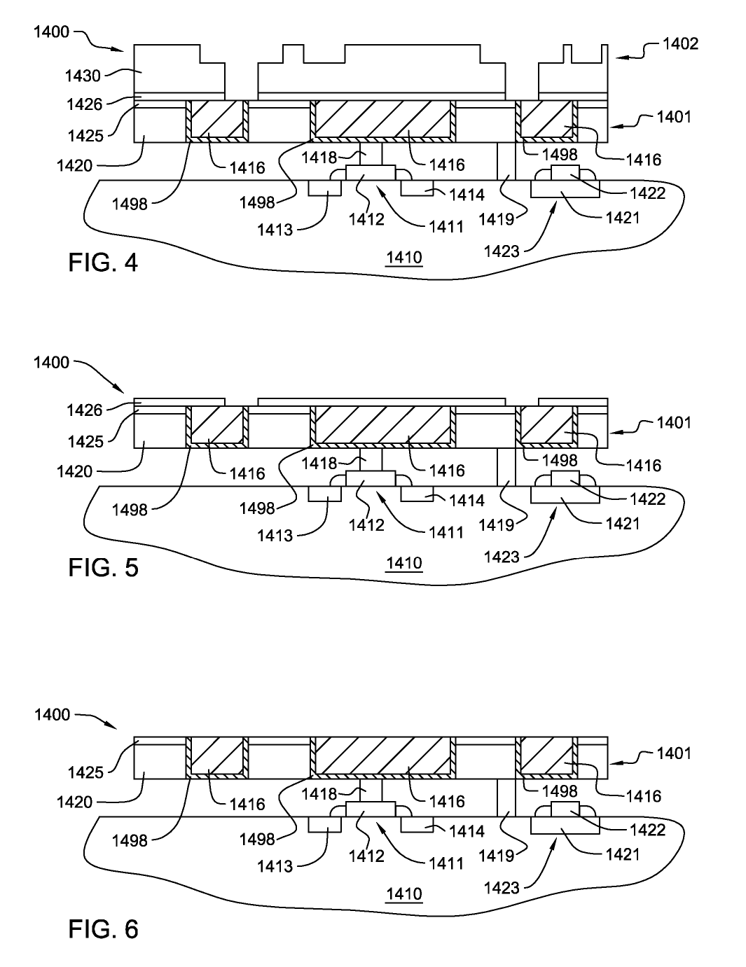

A number of different processes can be used to remove the upper wiring level 1402. For example, a copper etch (such as dilute H₂SO₄/H₂O₂, etc.) can be used to remove the conductor 1415, as shown in FIG. 3. Then, a liner etching process can be used to remove the liner 1490, as shown in FIG. 4. For example, the liner 1490 is removed using H₂O₂ if tungsten is used for the liner 1490, or PFC, HFC, etc., HCL, BCL, plasma etching, RIE if Ta or TiN is used for the liner 1490.

In addition, rather that performing the multiple steps shown in FIGS. 3 and 4, a liner wet etchant (such as H₂O₂ for tungsten), which results in a conductor lift-off process, can be used to remove the liner and conductor in one step, as shown in FIG. 4. Since the underlying metal level 1401 is formed with a different material than the upper liner 1490, the lower liner 1498 will remain in tact and protect the conductor 1416.

Alternatively, the low k dielectric layer 1430 can be selectively removed 120 first, using known RIE techniques, leaving free-standing conductors 1415 and liners 1490. For example, if SiLK is used as the low k dielectric layer 1430, it can be performed using a standard plasma etch chemistry based on H or N. Then, the free-standing copper structures 1415 would be removed using, for example, a copper and CMP (chemical-mechanical polish) liner polish.

Alternatively, a well-known tape and peel process could be used to remove the upper wiring layer 1430. In yet another alternative, a CMP process can be used, wherein the entire second insulator layer 1430 and wiring conductors 1415 within the second metallization layer 1402 are removed via a CMP process, thereby leaving only the first metallization layer 1401 intact with its plurality of wiring conductors 1416 interspersed within the first insulator layer 1420 and the first hardmask layer 1425, which is illustrated in FIG. 6.

The invention provides an etchant that will attack only one of the liners 1490 and that will not affect the other liner 1498. The underlying metal layer 1416 is protected by the liner 1498 when the overlying metal liner 1490 is removed. The liners 1490, 1498 are not limited to just tungsten and tantalum. Instead, any conductive liners can be used that can be etched selectively with respect to one another. This allows the invention to easily and completely remove one metal layer without affecting the adjacent metal layer.

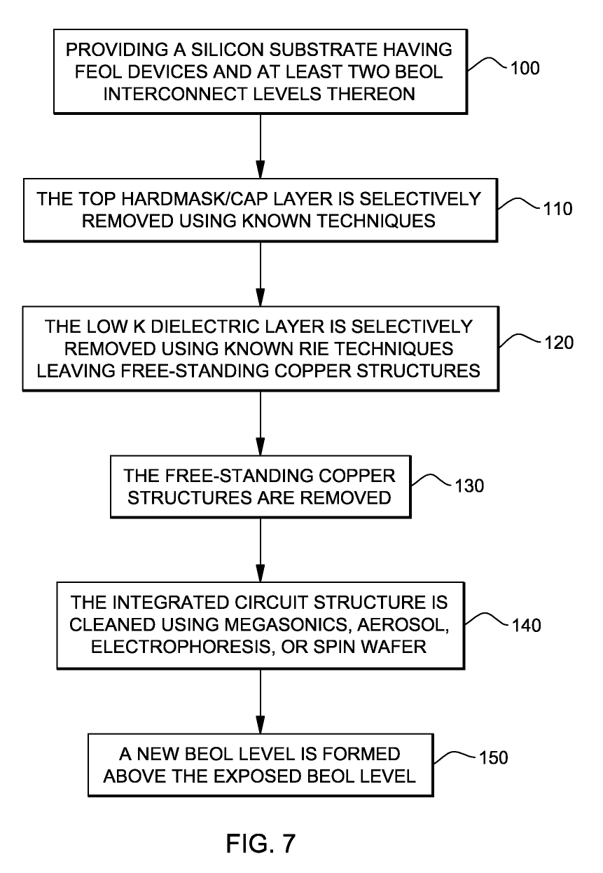

FIG. 7 illustrates a flow diagram of a rework process according to the present invention. The method of reworking BEOL (back end of a processing line) interconnect levels having different liner materials of damascene metallurgy comprises first providing 100 a silicon substrate having FEOL devices and at least two BEOL interconnect levels thereon. Next, the top hardmask/cap layer 1435 is selectively removed 110 using known techniques. Then, the low k dielectric layer 1430 is selectively removed 120 using known RIE techniques leaving free-standing copper structures 1415. Next, the free-standing copper structures 1415 are removed 130. The invention provides an etchant that will attack only one of the liners and that will not affect the other liner. Upon completion of the removal step 130, the integrated circuit structure 1400 is cleaned 140 using megasonics, aerosol, electrophoresis, or spin wafer. Finally, BEOL level rebuilding occurs, wherein a new BEOL level is formed 150 above the exposed BEOL level 1401.

With the invention, the liners of adjacent wiring levels comprise different materials that have different etching characteristics and that are selectively etchable with respect to one another. The invention provides an etchant that will attack only one of the liners and that will not affect the other liner. The underlying metal layer is protected its corresponding liner when the overlying metal liner is removed. This allows the invention to easily and completely remove one metal layer without affecting the adjacent metal layer.

While the invention has been described in terms of preferred embodiments, those skilled in the art will recognize that the invention can be practiced with modification within the spirit and scope of the appended claims.

What is claimed is:

1. A method of reworking wiring levels in a semiconductor structure, said wiring levels having liners at least partially surrounding conductors, said method comprising:
removing first conductors from a first wiring level,
wherein first liners, at least partially surrounding said first conductors within said first wiring level, protect second conductors of a second wiring level, adjacent said first wiring level, during said process of removing said first conductors,
said method further comprising removing said first liners from said first wiring level,
wherein said first liners comprise a different material than second liners in said second wiring level.

2. The method of claim 1, wherein said first liners comprise a material having different etching characteristics than second liners, and said first liners and said second liners are selectively etchable with respect to one another such that said process of removing said first liners does not affect said second liners.

3. The method of claim 1, wherein said liners comprise one of Ta, W, TiN, TaN, TaSiN, Sin.

4. The method of claim 1, further comprising removing an insulator surrounding said first liners in said first wiring level.

5. The method of claim 1, further comprising, after said removing of said first liners, planarizing said semiconductor structure to completely remove said first wiring level.

6. The method of claim 1, wherein said process of removing said first conductors comprises an etching process that attacks said conductors and does not attack said first liners or said second liners.

7. The method of claim 1, wherein said process of removing said first liners comprises a selective etching process that removes said first liners does not affect said second liners.

8. The method of claim 1, wherein said removing of said first liners comprises a reactive ion etch (RIE) process using a chemistry containing hydrofluorocarbon (HFC), perfluorocarbon (PFC), or HFC-PFC-Argon, with or without an oxidizer including O₂, CO, CO₂, NO, and NO₂.

9. The method of claim 1, wherein said first conductor comprises copper.

10. The method of claim 1, wherein said removing of said first conductor comprises a copper etch including dilute H₂SO₄, and H₂O₂

11. An interconnect wiring level method comprising:
a first conductor;
a first liner at least partially surrounding and contacting said first conductor;
a first insulator layer comprising a first dielectric material contacting only lateral sides of said first liner; and
a first hardmask layer over and adjacent to said first insulator layer and contacting said first liner;
a second conductor over said first conductor;
a second liner at least partially surrounding and contacting exactly three sides of said second conductor, wherein said second liner contacts said first conductor, said first liner, and only a top of said first hardmask layer;
a second insulator layer comprising a second dielectric material contacting said second liner; and
a plurality of etchable hardmask layers over said first hardmask layer and contacting said second liner,
wherein said first hardmask layer and one of said plurality of etchable hardmask layers contact one another, and
wherein said first liner comprises different materials than said second liner.

12. The interconnect wiring level method of claim 11, wherein said second insulator layer is structurally thicker in size than said first insulator layer.

13. The interconnect wiring level method of claim 11, wherein the first and second liners each comprise a single liner layer.

14. The interconnect wiring level method of claim 11, wherein said first liner contacts said second liner.

15. The interconnect wiring level method of claim 11, wherein said first liner is in a first wiring level and said second liner is in a second wiring level adjacent to said first wiring level.

16. The interconnect wiring level method of claim 11, wherein said different materials have different etching characteristics and are selectively etchable with respect to one another.

17. The interconnect wiring level method of claim 11, wherein the first and second liners comprise one of W, TiN, Ta, TaN, TaSiN, WN, and WSiN.

18. A semiconductor interconnect method comprising:
a first wiring level comprising:
a first conductor having a first shape;
a first liner at least partially surrounding and contacting exactly three sides of said first conductor;
a continuous first insulator layer comprising a first dielectric material contacting a side of said first liner; and
a first hardmask layer over and adjacent to said first insulator layer and contacting a side of said first liner;
a second wiring level over and adjacent to said first wiring level, said second wiring level comprising:
a second conductor having a second shape;
a second liner at least partially surrounding and contacting all but an upper side of said second conductor, wherein said second liner contacts said first conductor, said first liner, and only a top of said first hardmask layer;
a third conductor having a shape substantially similar to said first shape of said first conductor;
a third liner at least partially surrounding and contacting exactly three sides of said third conductor;
a continuous second insulator layer comprising a second dielectric material contacting a side of the second and third liners;
an etchable second hardmask layer over and contacting said second insulator layer and contacting a side of said second and third liners; and
an etchable third hardmask layer over and contacting said first hardmask layer and said first liner and said first conductor and contacting a side of said second liner, wherein said first hardmask layer and said etchable second hardmask layer contact one another, and
wherein said first liner comprises different materials than the second and third liners.

19. The semiconductor interconnect method of claim 18, wherein said second insulator layer is structurally thicker in size than said first insulator layer.

20. The semiconductor interconnect method of claim 18, wherein the first, second, and third liners each comprise a single liner layer.
